(19) United States
(12) Patent Application Publication
(10) Pub. No.: US 2012/0194897 A1
(43) Pub. Date: Aug. 2, 2012

(54) BACKSIDE PATTERNING TO FORM SUPPORT POSTS IN AN ELECTROMECHANICAL DEVICE

(75) Inventors: Fan Zhong, Fremont, CA (US); Sapna Patel, Fremont, CA (US)

(73) Assignee: QUALCOMM MEMS Technologies, Inc., San Diego, CA (US)

(21) Appl. No.: 13/014,973

(22) Filed: Jan. 27, 2011

(51) Int. Cl. G02B 26/00; H01L 33/60

(52) U.S. Cl. 359/291; 438/29; 257/E33.072

(57) ABSTRACT

This disclosure provides systems, methods and apparatus for backside patterning of structures in electromechanical devices. In one aspect, backside patterning of supports in an electromechanical device allows the size of the supports to be reduced, increasing the active region of the electromechanical device. In electromechanical devices having black masks, the black masks may include a partially transmissive aperture aligned with the supports which enable backside patterning of the support through the black mask. The black mask may include an interferometric black mask in which an upper reflective layer has been patterned to form an aperture extending therethrough.

### TECHNICAL FIELD

This disclosure relates to electromechanical systems and methods of fabricating the same using backside exposure.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of fabricating an electromechanical device, including forming a black mask over a substrate, where the black mask includes: an absorber layer, and an opaque layer having at least one aperture formed therein, forming a sacrificial layer over the substrate, where the sacrificial layer includes an opaque material, patterning the sacrificial layer to form at least one aperture extending through the sacrificial layer, where the at least one aperture extending through the sacrificial layer is aligned with the at least one aperture formed in the opaque black mask layer, forming a layer of structural material over the patterned sacrificial layer, forming a layer of negative photoresist over the structural material, exposing the negative photoresist to light through the substrate to form exposed portions of the negative photoresist, and using the exposed photoresist portions as a mask to etch the structural material to form a patterned structure.

The structural material can include support material, and etching the structural material to form at least one structure can include forming at least one support. The opaque layer can include a reflective layer, and the black mask can further include a spacer layer located over the absorber layer and below the opaque layer. The method can further include forming an optical stack over a substrate, where the sacrificial layer is formed over at least a portion of the optical stack, and forming a deformable reflective layer over the at least one support, where the deformable layer is electrostatically displaceable towards the optical stack. The support can be located substantially within the at least one aperture in the sacrificial layer.

Another innovative aspect of the subject matter described in this disclosure can be implemented in an electromechanical device, including a black mask formed over a substrate, the black mask including: an absorber layer, and an opaque layer having at least one aperture formed therein, at least one structure, where the at least one structure is aligned with the at least one aperture in the reflective layer, and a deformable layer spaced apart from underlying layers by a gap.

The at least one structure can include a support which spaces the deformable layer apart from underlying layers. The opaque layer can include a reflective layer, and the black mask can further include a spacer layer located over the absorber layer and below the opaque layer. The device can further include a conductive layer located over the black mask and separated from the deformable layer by a gap, where the deformable layer is electrostatically displaceable towards the conductive layer.

Another innovative aspect of the subject matter described in this disclosure can be implemented in an electromechanical device, including a stationary conductive layer supported by a substrate, a plurality of supports, a movable conductive layer generally spaced apart from the fixed conductive layer by an air gap, where the movable conductive layer is supported by the plurality of supports, and means for shielding at least a portion of the electromechanical device from light passing through the substrate, where the shielding means includes partially transmissive regions which allow at least a portion of light passing through the substrate to pass therethrough, where the partially transmissive regions underlie the plurality of supports.

Another innovative aspect of the subject matter described in this disclosure can be implemented in a method of fabricating an electromechanical device, the method including forming a sacrificial layer over a substrate, where the sacrificial layer includes an opaque material, patterning the sacrificial layer to form a patterned sacrificial layer with at least one aperture extending through the sacrificial layer, forming a layer of support material over the patterned sacrificial layer, forming a layer of negative photoresist over the layer of support material, exposing the layer of negative photoresist to light through the substrate to form exposed portions of the negative photoresist, using the exposed photoresist portions as a mask to etch the support material to form at least one support, depositing a layer of reflective material over the support, patterning the layer of reflective material to remove portions of the reflective material overlying and surrounding the support, and depositing a mechanical layer over the layer of reflective material. The method can further include forming an optical stack over the substrate prior to forming the sacrificial layer over the substrate.

Another innovative aspect of the subject matter described in this disclosure can be implemented in an electromechanical device, including a conductive absorber layer formed over a substrate, an insulating layer formed over the conductive absorber layer, a plurality of supports, where the plurality of supports are at least partially transmissive to light, a deformable layer spaced apart from the insulating layer by the plurality of supports, such the deformable layer and the insulating layer are separated by an air gap, where the deformable layer includes a mechanical sublayer, and a reflective sublayer located on the side of the mechanical layer facing the air gap, where the deformable layer is electrostatically actuatable towards the conductive absorber layer such that a substantial portion of the reflective sublayer is collapsed against an underlying layer. The mechanical sublayer can include a material which is less reflective than the reflective sublayer.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3A shows an example of a diagram illustrating movable reflective layer position versus applied voltage for the interferometric modulator of FIG. 1.

FIG. 3B shows an example of a table illustrating various states of an interferometric modulator when various common and segment voltages are applied.

FIG. 4A shows an example of a diagram illustrating a frame of display data in the 3×3 interferometric modulator display of FIG. 2.

FIG. 4B shows an example of a timing diagram for common and segment signals that may be used to write the frame of display data illustrated in FIG. 4A.

FIG. 5A shows an example of a partial cross-section of the interferometric modulator display of FIG. 1.

FIGS. 5B-5E show examples of cross-sections of varying implementations of interferometric modulators.

FIG. 6 shows an example of a flow diagram illustrating certain stages in an example of a process of making an interferometric modulator using a backside patterning process.

FIGS. 7A-7G show examples of cross-sectional views illustrating certain stages in the process of FIG. 6.

FIG. 8 shows an example of a top plan view of an interferometric modulator array in which supports are formed by a backside patterning process.

FIGS. 9A-9J show examples of cross-sectional views illustrating certain stages in the fabrication of the interferometric modulator of FIG. 8, taken along the line 9-9 of FIG. 8.

FIG. 10 shows an example of a cross-sectional view illustrating a stage in the fabrication of the interferometric modulator of FIG. 8, taken along the line 10-10 of FIG. 8.

FIG. 11 shows an example of a flow diagram illustrating certain stages in an example of a method of making an interferometric modulator using a backside patterning process.

FIG. 12 shows an example of a cross-sectional view illustrating an electromechanical device formed using a backside patterning process.

FIG. 13 shows an example of a flow diagram illustrating certain stages in an example of a method of making an interferometric modulator using a backside patterning process.

FIGS. 14A and 14B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to a person having ordinary skill in the art.

The fabrication of electromechanical devices may include the formation of structures which support deformable layers. In an optical electromechanical device, the portions of the deformable layer adjacent these supports may not be collapsed fully against underlying layers, causing potentially undesirable optical effects. Masks may be used to shield these areas, but doing so renders the masked area optically inactive. A black mask having an aperture therein may be used to facilitate the backside patterning process while shielding the portions of the device adjacent the resultant support during operation of the final device.

Particular implementations of the subject matter described in this disclosure can be implemented to realize one or more of the following potential advantages. Self-alignment of the support structures ensures that the support structures are properly aligned with underlying patterned areas, enabling the use of smaller support structures. By reducing the size of the supports through a self-aligning backside patterning process, the amount of masked area required to shield the areas adjacent the support post is similarly reduced. The size of optical area of the display can be increased, improving the brightness of the display.

An example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

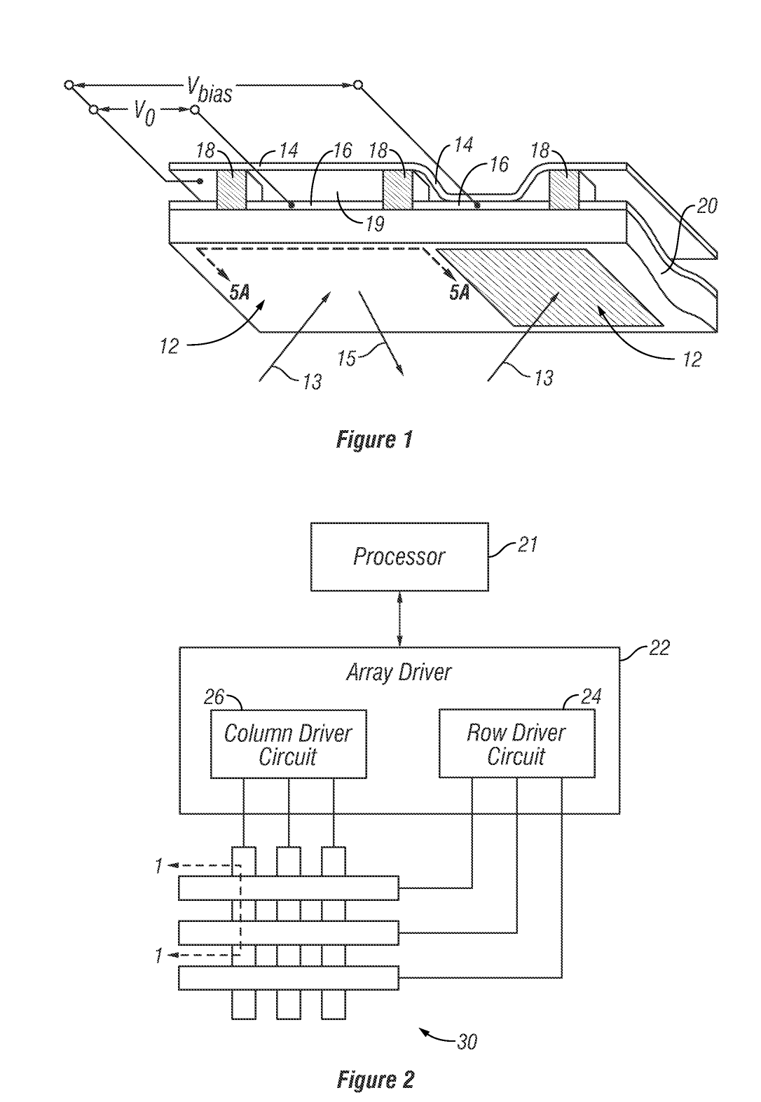

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be on the order of 1-1000 um, while the gap 19 may be on the order of <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

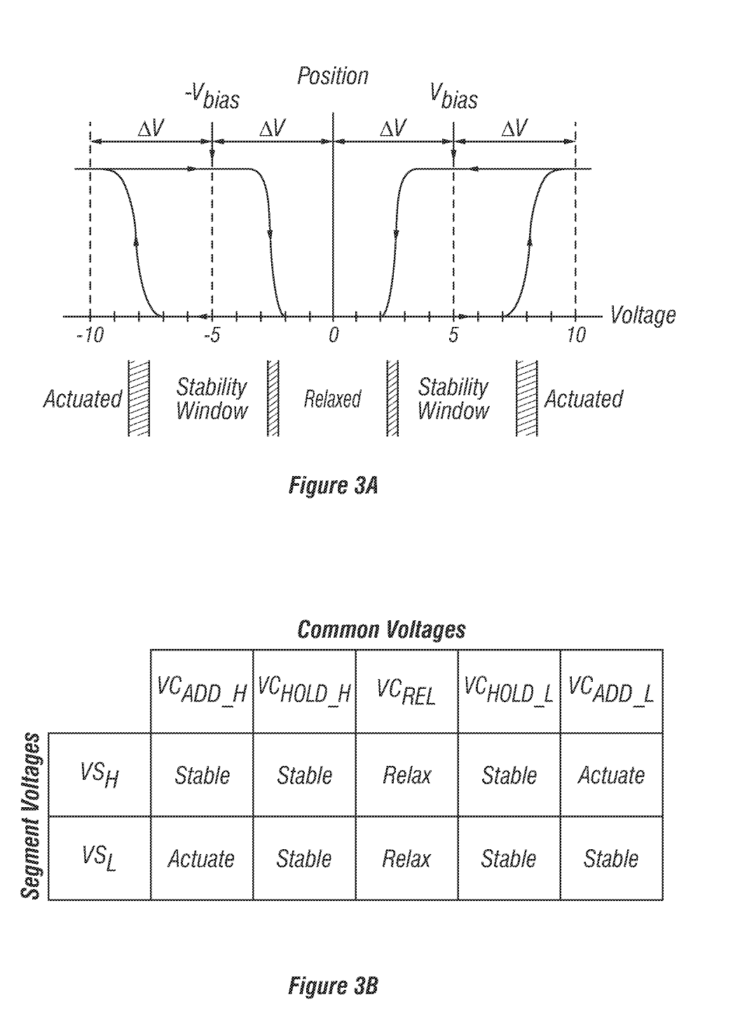

FIG. 3A shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3A. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3A, exists where there is a window of applied voltage within which the device is stable in either the relaxed or actuated state. This is referred to herein as the “hysteresis window” or “stability window.” For a display array 30 having the hysteresis characteristics of FIG. 3A, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 3B shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

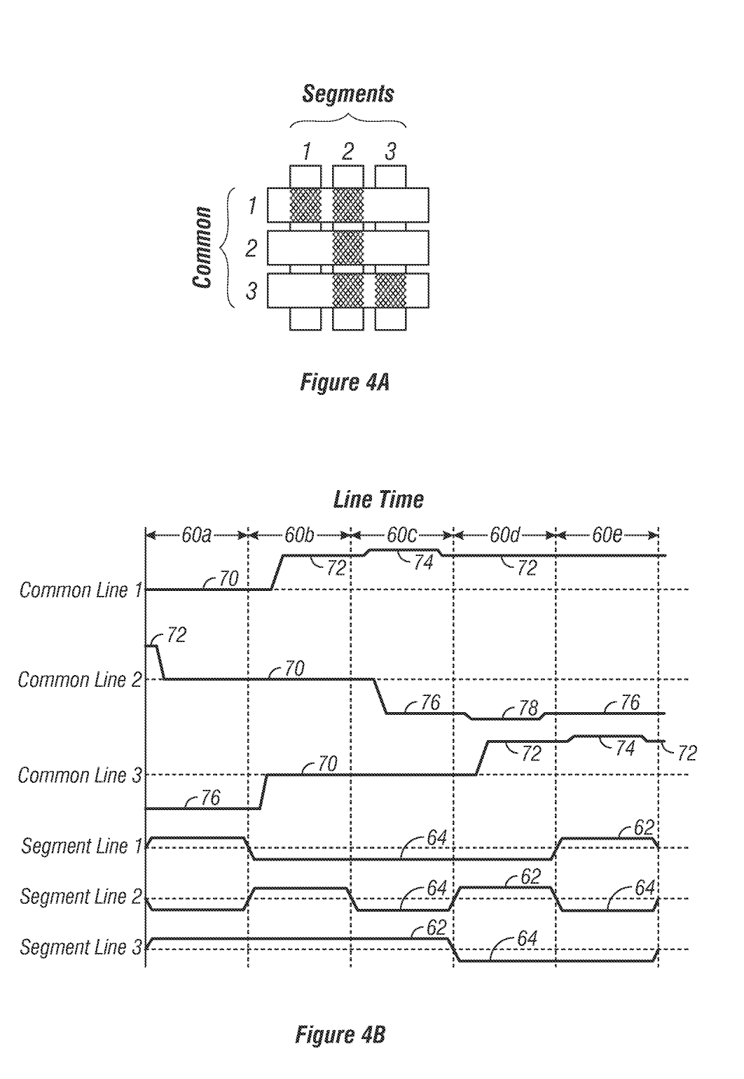

As illustrated in FIG. 3B (as well as in the timing diagram shown in FIG. 4B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3A, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 4A shows an example of a diagram illustrating a frame of display data in the 3×3 interferometric modulator display of FIG. 2. FIG. 4B shows an example of a timing diagram for common and segment signals that may be used to write the frame of display data illustrated in FIG. 4A. The signals can be applied to the, e.g., 3×3 array of FIG. 2, which will ultimately result in the line time 60e display arrangement illustrated in FIG. 4A. The actuated modulators in FIG. 4A are in a dark-state, i.e., where a substantial portion of the reflected light is outside of the visible spectrum so as to result in a dark appearance to, e.g., a viewer. Prior to writing the frame illustrated in FIG. 4A, the pixels can be in any state, but the write procedure illustrated in the timing diagram of FIG. 4B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 3B, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 4A, and will remain in that state as long as the hold voltages are applied along the common lines, regardless of variations in the segment voltage which may occur when modulators along other common lines (not shown) are being addressed.

In the timing diagram of FIG. 4B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 4B. In some other implementations, voltages applied along common lines or segment lines may vary to account for variations in the actuation and release voltages of different modulators, such as modulators of different colors.

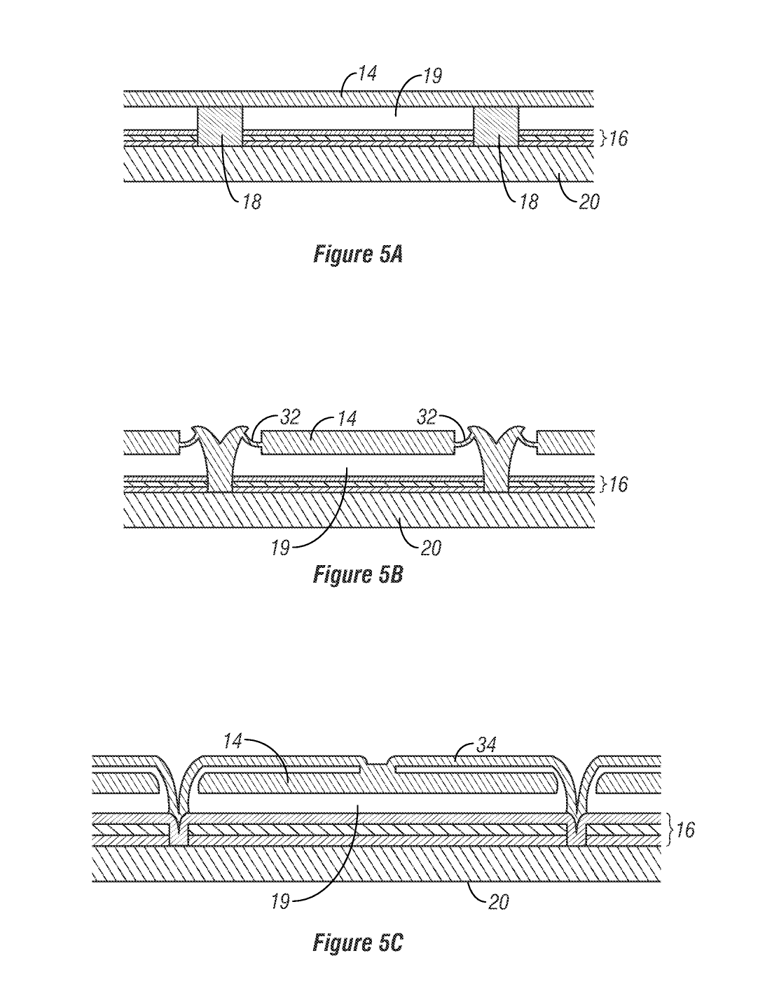

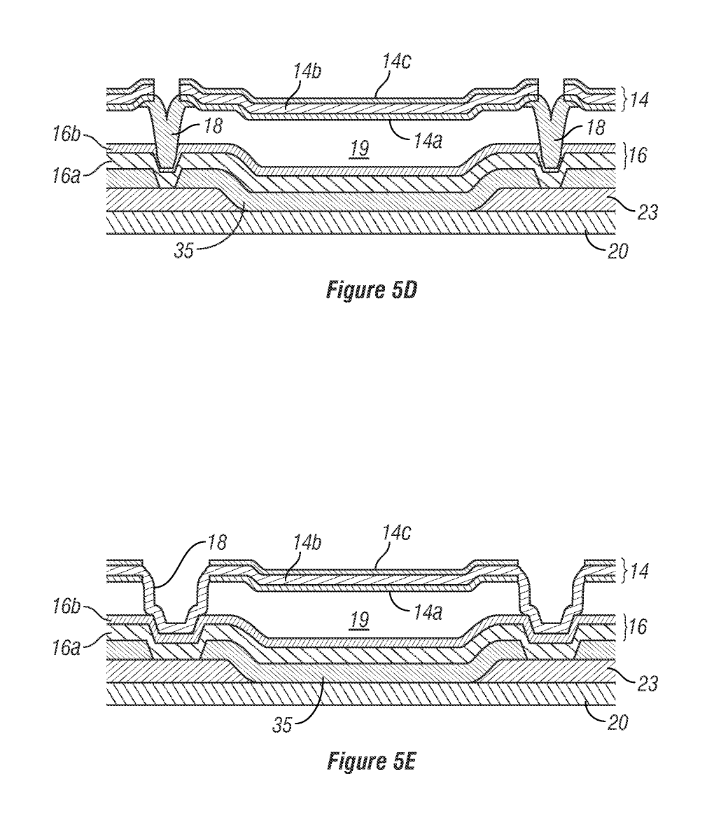

The details of the structure of interferometric modulators that operate in accordance with the principles set forth above may vary widely. For example, FIGS. 5A-5E show examples of cross-sections of varying implementations of interferometric modulators, including the movable reflective layer 14 and its supporting structures. FIG. 5A shows an example of a partial cross-section of the interferometric modulator display of FIG. 1, where a strip of metal material, i.e., the movable reflective layer 14 is deposited on supports 18 extending orthogonally from the substrate 20. In FIG. 5B, the movable reflective layer 14 of each IMOD is generally square or rectangular in shape and attached to supports at or near the corners, on tethers 32. In FIG. 5C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 5C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 5D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 5D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 5E shows another example of an IMOD, where the movable reflective layer 14 is self supporting. In contrast with FIG. 5D, the implementation of FIG. 5E does not include separately deposited support material. Instead, the movable reflective layer 14 contacts the underlying optical stack 16 at multiple locations to serve as the support posts 18, and the curvature of the movable reflective layer 14 proximate those locations provides sufficient support that the movable reflective layer 14 returns to the unactuated position of FIG. 5E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 5A-5E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 5C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 5A-5E can simplify processing, such as, e.g., patterning.

When an electromechanical device such as the interferometric modulator of FIG. 5A, is actuated to move the deformable layer 14 towards the optical stack 16, the deformable layer in the region surrounding the support structures 18 will not come in contact with the optical stack. Thus, when in a collapsed or actuated position, the deformable layer 14 will thus extend downward from the support post 18 until it contacts the optical stack 16 at a point some distance from the support post 18. In various implementations, it may be desirable to decrease the size of the support posts in order to increase the amount of the deformable layer which is collapsed against an underlying layer. For example, in an optical MEMS device such as an interferometric modulator, this region surrounding the support post will have a different optical response to incident light than will the region in which the deformable layer is collapsed against the optical stack. In non-optical implementations, however, it may be similarly desirable to decrease the size of the support posts.

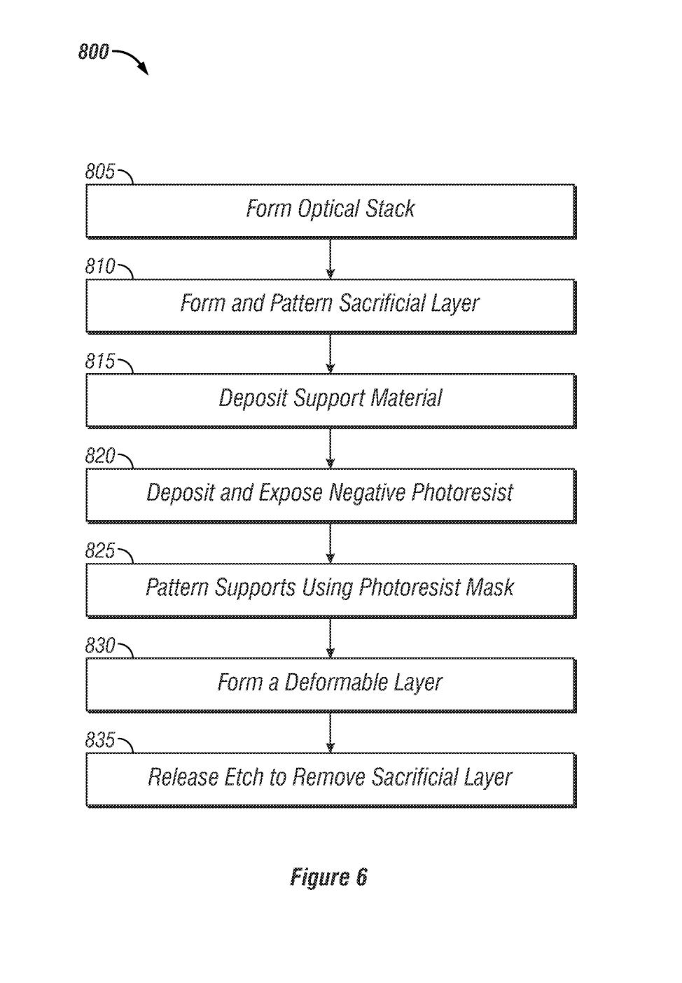

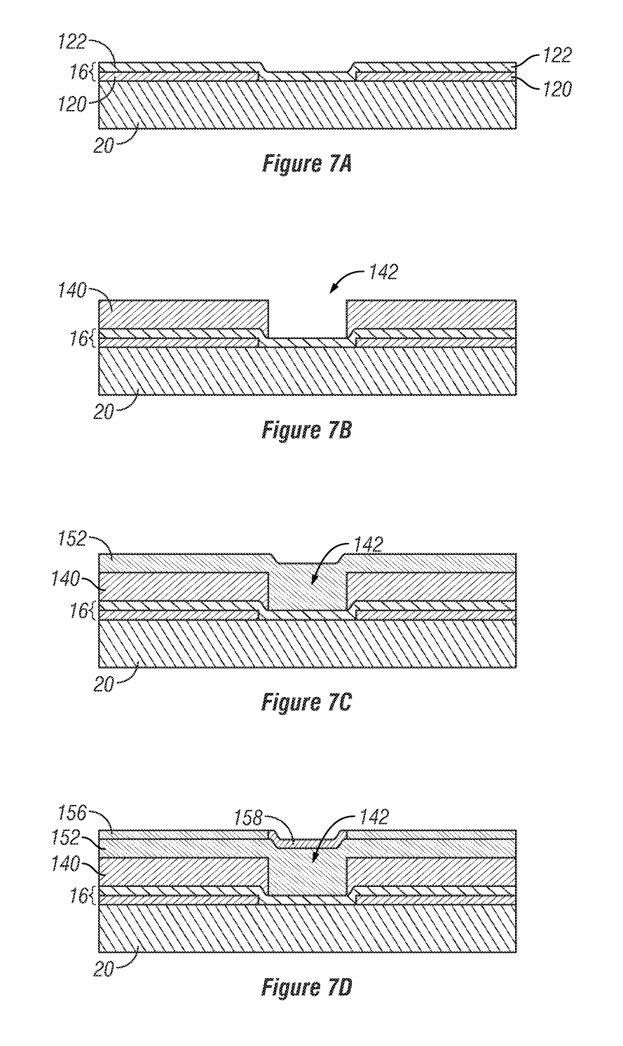

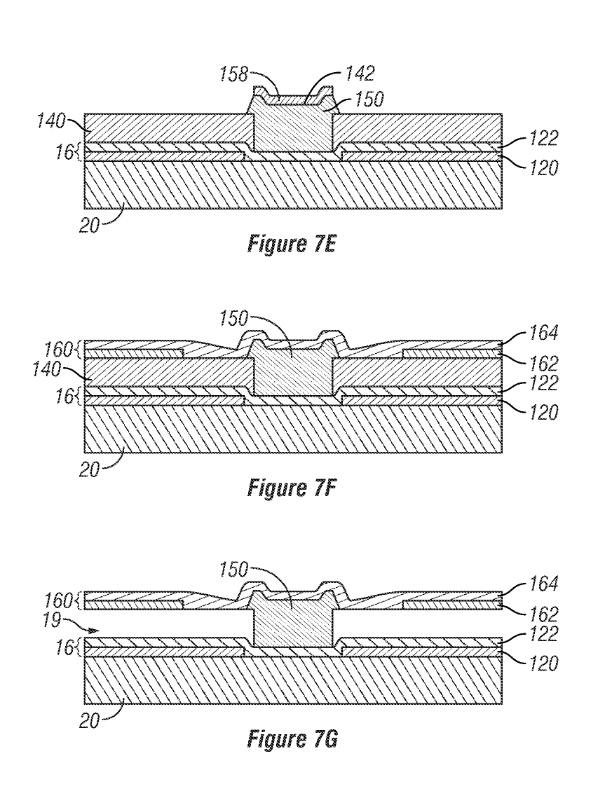

FIG. 6 shows an example of a flow diagram illustrating certain stages in an example of a method of making an interferometric modulator using a backside patterning process 800. FIGS. 7A-7G show examples of cross-sectional views illustrating certain stages in the method of FIG. 6. Such stages may be present in a process for manufacturing, e.g., interferometric modulators of the general type illustrated in FIGS. 1 and 5, along with other stages not shown in FIG. 6. With reference to FIGS. 1, 6 and 7A-7E, the process 800 begins at block 805 with the formation of the optical stack 16 over the substrate 20. FIG. 7A illustrates such an optical stack 16 formed over the substrate 20. The substrate 20 may be transparent in the visible range, such as glass or plastic, and may have been subjected to prior preparation step(s), e.g., cleaning, to facilitate efficient formation of the optical stack 16.

As discussed above, the optical stack 16 at least includes an electrically conductive layer, is partially transparent and partially reflective in some implementations and may be fabricated, for example, by depositing one or more of the layers onto the transparent substrate 20. In particular, it can be seen that the optical stack 16 of FIG. 7A includes a multilayer structure including sublayers 120, and 122, although more or fewer sublayers may be included in other implementations. In some implementations, a single conductive absorber sublayer 120 having suitable optical and electrical properties may be used to additionally serve as the primary conductor in this device's stationary lower electrode. In some other implementations, one sublayer includes a partially reflective layer or absorber layer selected for its optical properties, and another sublayer includes a conductive layer selected for its conductive properties to serve as the stationary electrode's primary conductor. In some implementations, one or more of the sublayers are patterned into parallel strips, and may form row or column electrodes in a display device. Such patterning may be done by a masking and etching process, but alternative methods of patterning are discussed in greater detail below. In some implementations, the optical stack 16 includes an insulating or dielectric layer, such as sublayer 122 of FIG. 7A, that is deposited over one or more metal layers (e.g., conductive absorber sublayer 120). The dielectric sublayer 122 can serve to prevent the stationary and movable electrodes from shorting during operation, and also can serve as an etch stop during subsequent processing. Alternately, additional layer(s) can be provided as etch stop(s). In non-optical electromechanical devices, the absorber layer 120 may be replaced with an appropriate conductive layer without regard for the optical properties of the conductive layer.

The process 800 illustrated in FIG. 6 continues at block 810 with the formation of a sacrificial layer 140 over the optical stack 16, followed by the patterning of the sacrificial layer 140 to form apertures 142. The sacrificial layer 140 is later removed (e.g., at block 835) to form the electromechanical device's gap or cavity 19 as discussed below and thus the sacrificial layer is not shown in the resulting interferometric modulator 12 illustrated in FIG. 1. FIG. 7B illustrates a partially fabricated device including a patterned sacrificial layer 140 formed over the optical stack 16. The formation of the sacrificial layer 140 over the optical stack 16 may include deposition of a fluorine-etchable material such as molybdenum or tungsten, in a thickness selected to provide, after subsequent removal, a cavity 19 (see FIGS. 1 and 7A) having the desired size. The skilled artisan will appreciate that other sacrificial materials and etch chemistries can be used, as long as the sacrificial layer 140 can be selectively removed relative to other exposed, permanent structures. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 800 illustrated in FIG. 6 continues at block 815 with the deposition of support material which will be used to form a support e.g., a post 18 as illustrated in FIGS. 1, and 5A-5E. In FIG. 7C, a layer of support material 152 (e.g., a polymer or a dielectric layer) has been deposited over the sacrificial layer 140 using a deposition method such as PECVD, thermal CVD, or spin-coating. Although the layer of support material 152 is illustrated as substantially conformal with a depression in the center of the aperture 142, other methods of deposition can be used. For example, a spin-coating process may be used which would result in a substantially planar upper surface of the support layer 152. In some implementations, a more conformal deposition process may be used which would result in a more pronounced depression in the interior of the aperture 142, even to the extent that the depression could extend below the height of the sacrificial layer 140. In implementations in which the distance between a movable layer and a fixed layer is important to the operation of the electromechanical device, it may be desirable that the support layer 152 has a height at least as high as the sacrificial layer 140 at the edges of the aperture 142. In some such implementations, a stiff, inorganic material may be used for the support layer 152. In addition, the support layer 152 may be substantially transmissive to certain wavelengths of light (e.g., UV light used for exposing photoresist) relative to the sacrificial layer 140.

The process 800 illustrated in FIG. 6 continues at block 820 with the formation of a layer of negative photoresist over the support layer 152. In FIG. 7D, a layer of negative photoresist 156 has been deposited over the support layer 152, and the photoresist layer 156 has been exposed to light from the underside of substrate 20 through the aperture 142 in the sacrificial layer 140. So long as the support layer 152 is substantially transmissive to appropriate wavelengths of light relative to the sacrificial layer 140, the portion 158 of the negative photoresist layer 156 can be exposed and become insoluble, and the remainder of the negative photoresist layer 156 will remain soluble. It can be seen in FIG. 7D that the exposed portion 158 of the photoresist 156 is substantially aligned with the aperture 142 in the sacrificial layer 140, due to the use of the sacrificial layer 140 as a photomask in the backside exposure patterning process.

The process 800 illustrated in FIG. 6 continues at block 825 with the formation of a support such as the posts 18 illustrated as illustrated in FIGS. 1 and 5A-5E. In FIG. 7E, the soluble portion of the photoresist 156 (see FIG. 7D) has been removed, and the exposed portion 158 of the photoresist has been used as a mask to pattern the support layer 152 (see FIG. 7D) to form support structures or supports 150. Because the exposed portion 158 of the photoresist is substantially aligned with the aperture 142 in the sacrificial layer 140, the resultant support structure 150 will be similarly aligned, and the size of any wing portion extending outward over the sacrificial layer 140 will be minimized and can be controlled by the etch process used for patterning. Because the exposed portion 158 serves as a self-aligned mask, the mask can be made smaller than the mask used in a conventional masking and patterning process, as the self-alignment process ensures that the mask will overlie the aperture. Supports formed by masks which are not self-aligned tend to include wing portions extending a greater distance outward over the sacrificial layer than the supports 150 of FIG. 7E in order to ensure overlap despite any misalignment, reducing the optically active area of the electromechanical device.

In some implementations, such as the implementation illustrated in FIG. 7E, the aperture formed in the sacrificial layer extends through the sacrificial layer, but not through the optical stack 16. In other implementations, supports 150 may extend through both the sacrificial layer 140 and the optical stack 16 to the underlying substrate 20, so that the lower end of the post 18 contacts the substrate 20 as illustrated in FIG. 5A. In some implementations, the supports 150 may be located largely within the apertures 142, as illustrated in FIG. 7E, but in other implementations a greater portion of the support structure may extend over a portion of the sacrificial layer 140.

The process 800 illustrated in FIG. 6 continues at block 830 with the formation of a movable reflective layer or membrane such as the movable reflective layer 14 illustrated in FIGS. 1 and 5, also referred to herein as a deformable layer. In FIG. 7F, the exposed portion 158 (FIG. 7E) of the photoresist layer has been removed, and a deformable layer 160 has been deposited over the sacrificial layer 140. As discussed above, portions of the deformable layer 160 are typically electrically conductive, and thus, the deformable layer 160 may be referred to herein as an electrically conductive layer. In some implementations, the deformable layer 160 may include a plurality of sublayers as shown in FIG. 7F. The deformable layer 160 may be formed by employing one or more deposition steps, along with one or more patterning, masking, and/or etching steps. In the illustrated implementation, the layer 160 includes a reflective portion 162, or reflective sublayer, and a mechanical portion 164, or mechanical sublayer, although in other devices such as non-optical electromechanical devices, the deformable layer may be a single layer, or may consist of another combination of layers. In some implementations, the mechanical portion 164 may include a dielectric material (see, e.g., discussion of FIG. 5D above), and may also be substantially transmissive to incident light. In some other implementations, the mechanical portion 164 may include a layer which is at least partially opaque to incident light, but is less reflective than the reflective portion 162.

In the illustrated implementation, the reflective sublayer 162 is located some distance away from the supports 150. This may be done, for example, by depositing and patterning the reflective sublayer 162 before depositing the mechanical layer 164. Because the support 150 is at least somewhat transmissive to light, the lack of a reflective sublayer 162 overlying the support post minimizes undesirable optical effects which could result from the reflection of light through the support posts if the reflective sublayer 162 were to overlie the supports 150 during operation of the finished device.

In non-optical electromechanical devices, the deformable layer 160 need not include a material selected for its reflective properties, and may instead include one or more layers selected for their mechanical or electrical properties.

Since the sacrificial layer 140 is still present in the partially fabricated interferometric modulator formed at block 830 of the process 800, the movable reflective layer 160 is typically not movable at this stage. A partially fabricated interferometric modulator that contains a sacrificial layer 140 may be referred to herein as an “unreleased” interferometric modulator, and non-optical devices may be referred to as unreleased electromechanical devices at this stage.

The process 800 illustrated in FIG. 6 continues at block 835 with the formation of a cavity, e.g., a cavity 19 as illustrated in FIGS. 1 and 5. In FIG. 7G, a release etch has been performed to remove the sacrificial layer 140 (see FIG. 7F) to form a cavity 19, allowing the deformable layer 160 to be electrostatically displaced in operation to move through the gap or cavity 19 towards the stationary electrode sublayer 120. The cavity 19 may be formed by exposing the sacrificial material 140 (deposited at step 810) to an etchant. For example, an etchable sacrificial material such as molybdenum or tungsten may be removed by dry chemical etching, e.g., by exposing the sacrificial layer to a gaseous or vaporous etchant, such as fluorine-based vapors derived from solid xenon difluoride (XeF₂) for a period of time that is effective to remove the desired amount of material, selectively relative to the structures surrounding the cavity 19. Other etching methods, e.g., selective wet etching and/or plasma etching, may also be used. Since the sacrificial layer is removed during block 835 of the process 800, the deformable layer 160 is typically movable after this stage. After removal of the sacrificial material 140, the resulting fully or partially fabricated interferometric modulator may be referred to herein as a “released” interferometric modulator.

In some implementations, the reflective portion 162 may be located a sufficient distance from the support post so that all or most of the reflective portion 162 will remain substantially parallel to the underlying layer when the deformable layer 160 is collapsed against the underlying layers. Such a configuration minimizes undesirable optical effects which may result from the varying distance between the reflective surface and other layers within the electromechanical devices, such as the fixed optical stack.

In order to avoid such undesirable optical effects, a mask also can be provided which may extend below the support post, and may extend outward to cover the area proximate support structures in which the deformable layer will not contact the optical stack. This mask may take multiple forms, but in some implementations, the mask may be an interferometric black mask which interferometrically produces a black appearance (e.g., a black etalon) by not reflecting substantial amounts of light in the visible wavelengths.

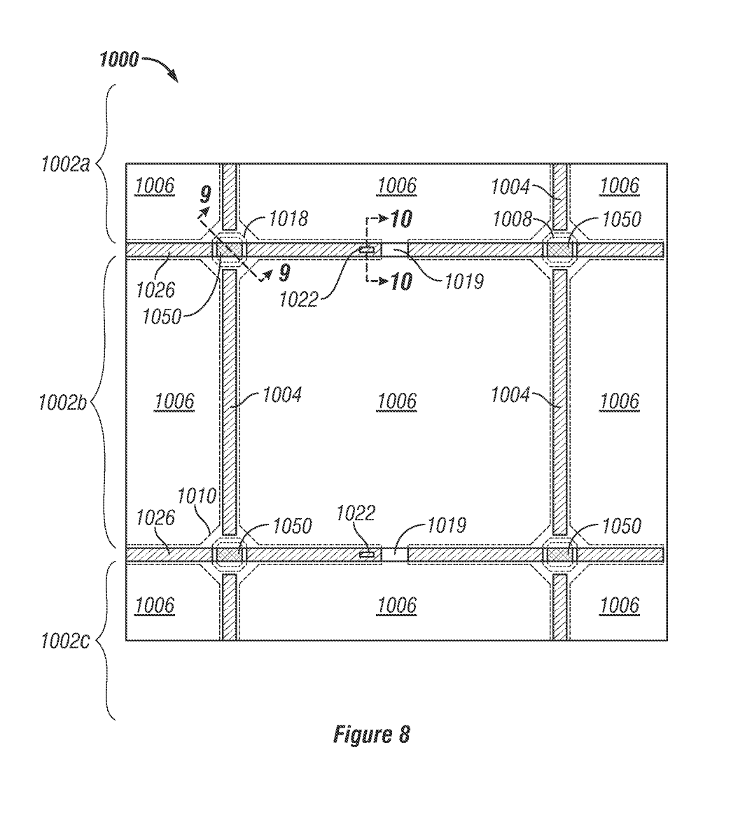

FIG. 8 shows an example of a top plan view of an interferometric modulator array in which supports are formed by a backside patterning process. The interferometric modulator array 1000 includes an interferometric black mask 1010 configured to permit backside patterning of supports 1050. The interferometric modulator array 1000 includes a movable or mechanical layer which has been patterned into horizontally extending strips 1002a, 1002b and 1002c separated by horizontal cuts 1026. Vertical slot cuts 1004 have been formed in the horizontally extending strips 1002a, 1002b and 1002c to separate the strips into subpixels 1006 which are connected to one another by thin bands 1008. In the illustrated implementation, the slot cuts 1004 are formed in the section of the strips extending between supports 1050, such that each subpixel 1006 is supported at four corners by supports 1050. The slot cuts 1004 mechanically decouple adjacent subpixels, to allow a subpixel to be actuated by electrostatically collapsing the mechanical layer towards an underlying stationary electrode without resulting in deformation at the edges of the mechanical layer of devices of adjacent subpixels.

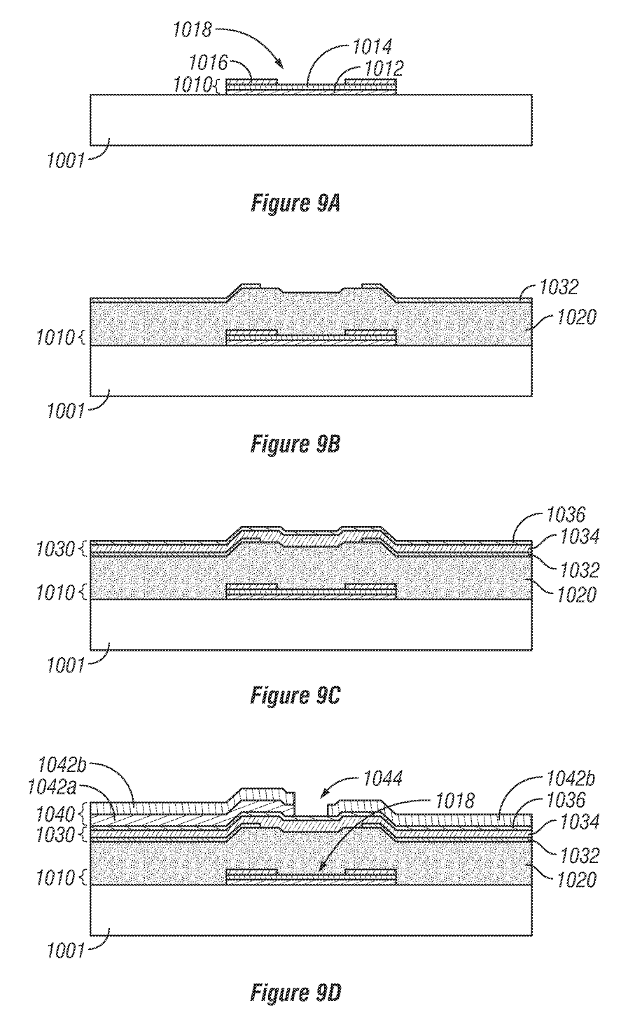

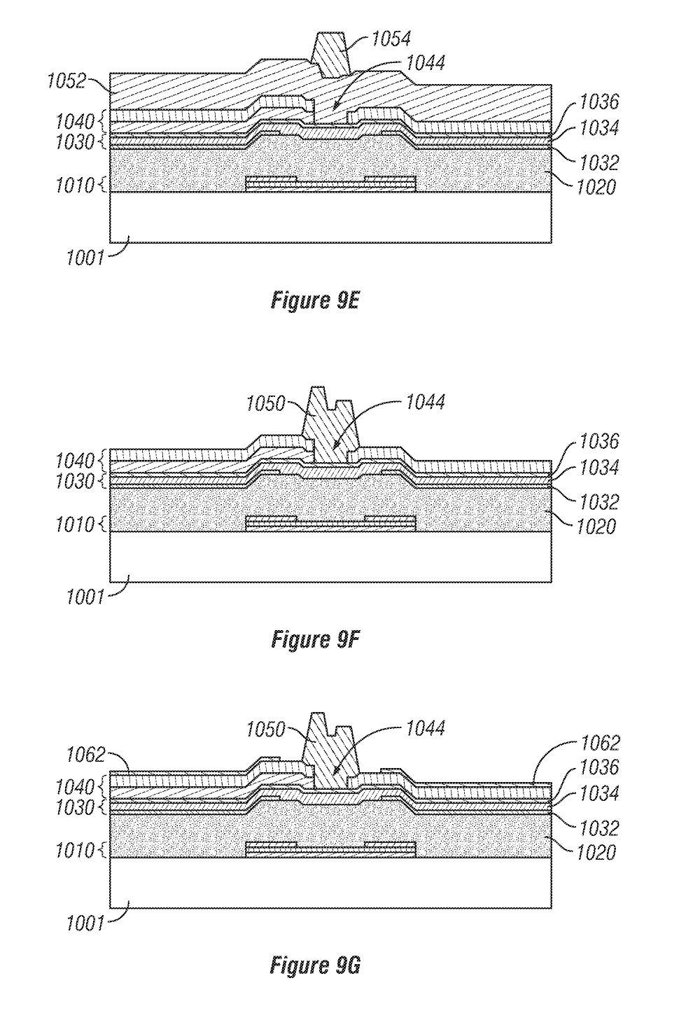

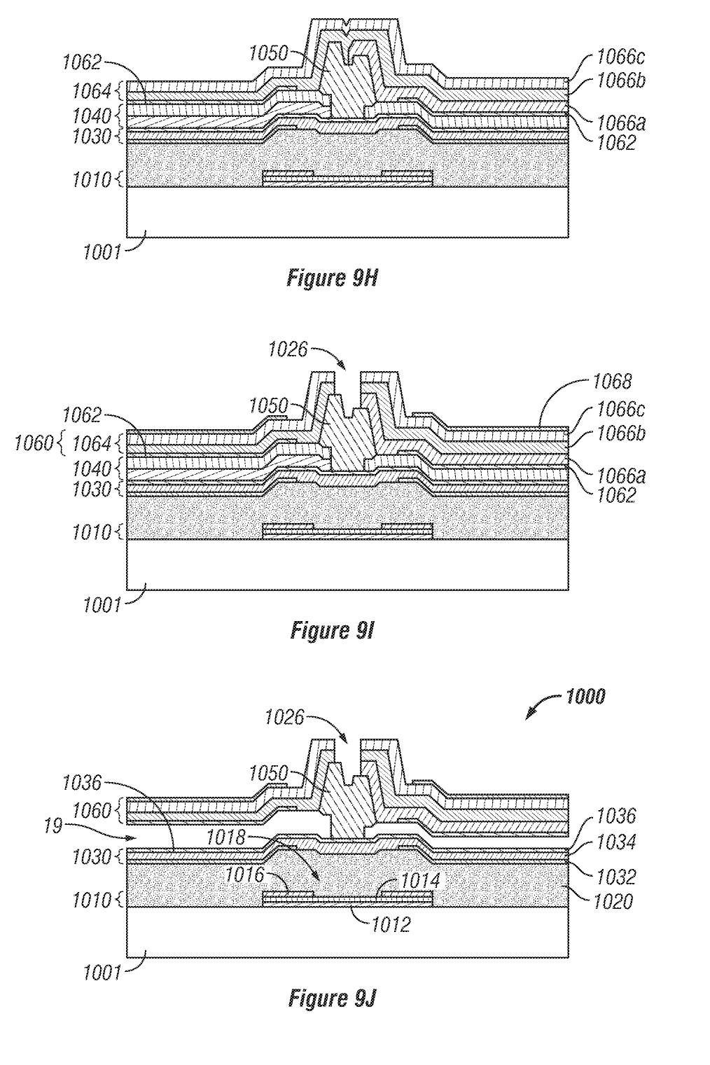

The interferometric black mask 1010 extends between subpixels 1006 and surrounds supports 1050. In particular, the interferometric black mask 1010 forms an aperture 1018 underlying the support post and extending slightly beyond the edges of the support 1050. The aperture 1018 allows at least some light to pass therethrough and into the area overlying the aperture 1018. Because light can pass through the aperture 1018, a process employing backside patterning can be used to pattern an overlying layer to form a support or support post as discussed with respect to FIGS. 7A-7G, despite the presence of the black mask 1010. The size and shape of the black mask aperture 1018 will control the size and shape of an aperture in the sacrificial layer (such as aperture 1044 of FIG. 9D), which will in turn affect the size and shape of the support 1050. The size and shape of the support structure 1050 will determine the manner in which the mechanical layer will deform. Thus, although the portions of the black mask 1010 surrounding the supports 1050 are illustrated as octagonal, the shape of the black mask 1010 in these areas will be dependent upon the size and shape of the supports 1050, as the black mask 1010 is configured to shield the portions of the mechanical layer which do not collapse fully against the underlying optical stack when a subpixel is actuated. Cuts 1019 in the interferometric black mask separate the interferometric black mask into electrically isolated sections which extend vertically or perpendicular to the horizontally extending strips, allowing the black mask 1010 to serve as a bussing layer.

FIGS. 9A-9I show examples of cross-sectional views illustrating certain stages in the fabrication of the interferometric modulator of FIG. 8, taken along the line 9-9 of FIG. 8. In FIG. 9A, an interferometric black mask 1010 has been formed on a substrate 1001. The interferometric black mask includes a partially reflective thickness of an absorber layer 1012 (e.g., metallic or semiconductor), a spacer layer 1014, and a reflective layer 1016. In some implementations, the absorber layer 1012 may include a molybdenum-chromium (MoCr) alloy, the spacer layer 1014 may include a dielectric such as SiO₂, SiNₓ, or SiOₓN_{y}, and the reflective layer 1016 may include aluminum or an aluminum alloy such as aluminum-silicon or aluminum-copper alloy, although other materials may also be used. At least the reflective layer 1016 has been patterned to form an aperture 1018, although a corresponding aperture may also be formed in the spacer layer 1014. The height of spacer layer 1014 can be selected such that the black mask 1010 serves to interferometrically produce a black appearance in the annular exterior region defined by the annular reflective layer 1016 while still permitting some light to pass through the absorber layer 1012 and the aperture 1018 in the reflective layer 1016.

In FIG. 9B, a spacer or buffer layer 1020 has been deposited over the interferometric black mask 1010. A semitransparent thickness of an absorber layer 1032 (e.g., metallic or semiconductor) has been deposited over the buffer layer 1020, and patterned to remove portions of the absorber layer 1032 located over the aperture 1018 in the black mask 1010. The absorber layer 1032 may be patterned into strip electrodes at this time, as well, to serve as stationary electrodes for the electromechanical devices. In some implementations, the buffer layer 1020 may include a dielectric material such as SiO₂, SiNₓ, or SiOₓN_{y}, and the absorber layer 1032 may include a partially reflective thickness of a MoCr alloy. The buffer layer 1020 provides a spacer layer between the black mask 1010 and the absorber layer 1032, allowing the patterning and etching of the absorber layer 1032 (e.g., to form a fixed electrode) without damaging the black mask 1010.

In FIG. 9C, an insulating layer 1034 is deposited over the absorber layer 1032 to form a bilayer optical stack 1030. An etch stop layer 1036 can be deposited over the optical stack 1030 to protect the insulating layer 1034 during patterning of a subsequently deposited sacrificial layer or sublayers and the release etch to remove the sacrificial layer. In some implementations, the etch stop layer 1036 may include an aluminum oxide, and the insulating layer 1034 may include SiO₂.

In FIG. 9D, a series of sacrificial sublayers 1042a and 1042b have been deposited and patterned in an iterative process. A first sacrificial sublayer 1042a is deposited and patterned, and a second sacrificial sublayer 1042b is deposited over the patterned first sacrificial sublayer 1042a. The second sacrificial sublayer 1042b is then patterned. A further sacrificial layer, not shown, may also be deposited and patterned. The sacrificial layers form a multilayer sacrificial layer 1040 which has at least two different thicknesses in different locations. The separate thicknesses allow the multilayer sacrificial layer 1040 to define different gap sizes for different electromechanical devices, such as interferometric gaps for three different colors of subpixels within the array 1000 of FIG. 8, such as red, green, and blue subpixels. In some implementations, the sacrificial sublayers may include molybdenum, although other suitable sacrificial layers may also be used. The sacrificial layer 1040 has also been patterned to form apertures 1044 which will be used to define the support structures 1050. The illustrated aperture 1044 has a smaller diameter than and is located within the region of the aperture 1018, ensuring that the black mask 1010 will not prevent light from entering any part of the aperture 1044. Rather, it is the multilayer sacrificial layer 1040 at the edges of the aperture 1044 that serves as a photomask during the subsequent exposure step discussed below to define the dimensions of the support.

In FIG. 9E, a layer of support material 1052 has been deposited over the patterned sacrificial layer 1040. The support material 1052 extends through the aperture 1044 in the patterned multilayer sacrificial layer 1040 to contact an underlying layer such as the etch stop layer 1036 or the optical stack 1030. A layer of negative photoresist material is also deposited over the support material 1052 and patterned by exposing the photoresist to light through the substrate 1001. As discussed with respect to FIG. 7C, this backside patterning process forms a negative photoresist mask 1054 which is self-aligned with the aperture 1044 in the opaque sacrificial layer 1040. Although the absorber layer 1012 in the black mask 1010 will absorb some of the light directed through the substrate, enough light will be transmitted through the absorber layer 1012 to expose the negative photoresist and render the exposed portions insoluble. The layer of support material 1052 may be a single layer of a stiff, inorganic material, or may include multiple sublayers. In some implementations, the layer of support material 1052 may include two sublayers of SiO₂ on opposite sides of a SiON layer.

In FIG. 9F, the layer of support material 1052 has been patterned using the negative photoresist mask 1054 to form supports 1050, and the mask 1054 has been removed. As discussed above with respect to FIG. 7E, because the mask 1054 was self-aligned with the aperture 1044 in the sacrificial layer 1040, the support structure does not extend significantly beyond the boundaries of the aperture 1044.

In FIG. 9G, a reflective layer 1062 has been formed over the patterned sacrificial layer 1040, and has been patterned to remove the portions of the reflective layer 1062 located over and immediately adjacent the support 1050. In some implementations, the reflective layer 1062 may include an aluminum-copper alloy, but other suitable materials may also be used. A thin AlOₓ layer (not shown) having a thickness of between 100-200 Å may also be deposited over the patterned reflective layer 1062, the support 1050, and exposed portions of the sacrificial layer 1040 to serve as an etch stop during patterning of a subsequently deposited dielectric mechanical layer.

In FIG. 9H, a series of dielectric mechanical sublayers 1066a, 1066b and 1066c have been deposited and patterned in a similar manner as the sacrificial sublayers of FIG. 9D to form a dielectric mechanical layer 1064 having as many as three different thicknesses. This may be done, for example, to provide a mechanical layer 1064 with varying stiffness in different colored subpixels. Typically thicker (stiffer) mechanical layers are desired for electromechanical devices having smaller gaps, to normalize the actuation voltages across devices of varying gap size. This may permit the use of a single actuation voltage in an array of devices with varying gap sizes. Because the dielectric mechanical layer 1064 (or another portion of the deformable layer 1060 in some other implementations) overlies at least a portion of the support 1050, the use of a transparent or less reflective mechanical layer may undesirable minimize reflection of light back through the support 1050 in the finished device.

In FIG. 9I, the dielectric mechanical layer 1064 has been patterned to form the slot cuts 1026 of FIG. 8, and a cap layer 1068 has been formed over the dielectric mechanical layer 1064 and patterned in the same manner as the reflective layer 1062, forming an opening which is wider than the support 1050. The three layers 1062, 1064 and 1068 together form the deformable layer 1060. It can be seen that the deformable layer 1060 has also been patterned to form the cuts 1026 dividing the horizontally extending strips 1002a, 1002b and 1002c of FIG. 8. Where the cap layer 1068 is identical to the reflective layer 1062 or has mechanical properties (such as the coefficient of thermal expansion) substantially similar to the reflective layer 1062, the cap layer 1068 may reduce undesired flexure or warping of the deformable layer 1060 due to differences in stresses within the various sublayers in the deformable layer 1060. In addition, removal of the cap layer 1068 overlying the support 1050 can reduce undesirable reflection of light through the support 1050 and the dielectric mechanical layer 1064 in implementations where the mechanical layer is light-transmissive.

Finally, in FIG. 9J, a release etch has been performed to remove the sacrificial layer 1040. This release etch, which can include multiple etches, may also remove at least a portion of the etch stop layer 1036 and any other etch stop layers which may be used. The removal of the sacrificial layer 1040 allows the deformable layer 1060 to be electrostatically displaced to move through the gap 19 towards the optical stack 1030. As can be seen in FIG. 9J, the layers overlying the aperture 1018 in the black mask 1010 may include layers which are at least sufficiently transmissive to light to chemically alter the overlying negative photoresist. However, although some light may bleed through, the absorber layer 1012 which extends across the black mask 1010 under the aperture 1018 will reduce the amount of light transmitted through the support post.

As noted above, use of an interferometric black mask allows the use of a metallic reflective layer as the upper layer of the interferometric black mask, which can simultaneously be used in other regions of the device (e.g., for routing in an interconnect area). The cuts 1019 (FIG. 8) in the interferometric black mask separate the interferometric black mask 1010 into electrically isolated sections which extend perpendicular to the horizontally extending strips 1002a, 1002b and 1002c, allowing the black mask to serve as an electrical signal bussing layer. In order to do so, vias 1022 (see FIG. 8) may be formed in the buffer layer 1020, allowing the absorber layer 1032 in the optical stack 1030 to contact the reflective layer 1016 in the underlying black mask 1010.

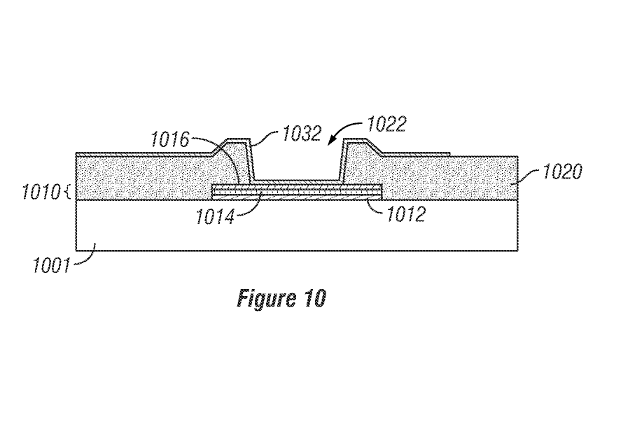

FIG. 10 shows an example of a cross-sectional view illustrating a stage in the fabrication of the interferometric modulator of FIG. 8, taken along the line 10-10 of FIG. 8. In particular, FIG. 10 represents a point in the process corresponding to the stages of FIG. 9B. It can be seen that the buffer layer 1020 was patterned after deposition to form a via 1022 in the form of an aperture extending through the buffer layer 1020. When the absorber layer 1032 is deposited as described in FIG. 9B, the absorber layer 1032 can be configured to be in contact with the upper reflective layer 1016 of the black mask 1010. The upper reflective layer 1016 can serve as a bussing layer within the optically shielded area of the display defined by the black mask. As can be seen in FIGS. 8 and 10, the portion of the black mask 1010 extending through line 10-10 is located away from the supports 1050 and the reflective layer 1016 at this location does not have an aperture formed therein.

While the above implementations have described the use of an interferometric black mask, other implementations may include a black mask which is not necessarily interferometric. Such a black mask may include an opaque layer having an aperture formed therein to allow backside patterning of a structure, along with an absorber layer to reduce the amount of light passing through the aperture in the opaque layer.

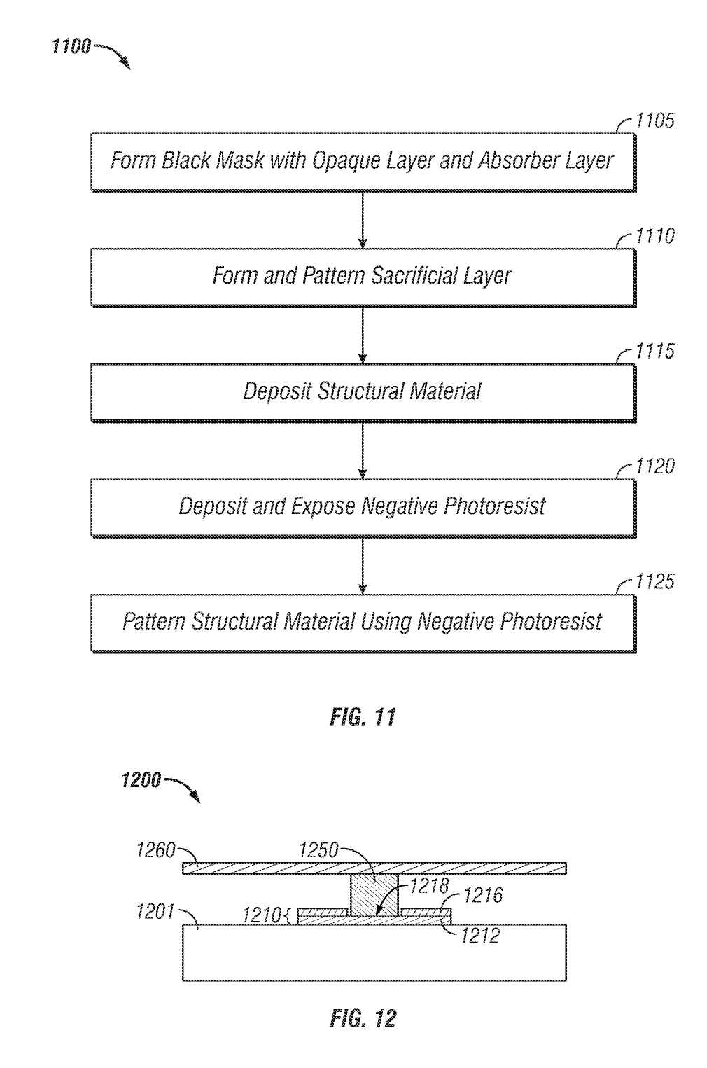

FIG. 11 shows an example of a flow diagram illustrating certain stages in an example of a process of making an electromechanical device using a backside patterning process. The process 1100 begins at block 1105 in which a black mask having an opaque layer and an absorber layer is formed on a light-transmissive substrate. In implementations in which the black mask is to be an interferometric black mask, the absorber layer may be formed between the opaque layer and the substrate, the opaque layer may be a reflective layer, and a spacer layer may also be formed between the opaque layer and the absorber layer. In implementations in which the black mask is not an interferometric black mask, either the opaque layer or the absorber layer may be formed first, as the relative positioning of these layers may be less important to the operation of the black mask. The opaque layer also can be patterned to form one or more apertures extending therethrough.

The process 1100 illustrated in FIG. 11 continues at block 1110, where an opaque sacrificial layer is deposited over the black mask and patterned to form at least one aperture extending therethrough and aligned with the at least one aperture extending through the absorber layer. In some implementations, additional layers may be formed after forming the black mask and prior to depositing the sacrificial layer, such as, e.g., those described above with respect to FIGS. 9B-9D.

The process 1100 illustrated in FIG. 11 continues at block 1115, where a structural material is deposited over the patterned sacrificial layer. The process 1100 continues at block 1120, where a negative photoresist is deposited over the structural layer and exposed from the opposite side of the substrate using a backside patterning process. The exposed negative photoresist forms a mask which is self-aligned with the aperture in the sacrificial layer.

Finally, the process 1100 illustrated in FIG. 11 continues at block 1125, where the structural material is patterned using the exposed negative photoresist as a mask to form a structure which is self-aligned with the aperture in the sacrificial layer.

FIG. 12 shows an example of a cross-sectional view illustrating an electromechanical device formed using a backside patterning process. The device 1200 includes a black mask 1210 formed over a light-transmissive substrate 1201. The black mask 1210 includes an absorber layer 1212 as well as an opaque layer 1216 having an aperture 1218 formed therein. A structure 1250, which in the illustrated implementation is a support, is aligned with the aperture 1218 in the opaque black mask layer 1216. A deformable layer 1260 is spaced apart from underlying layers such as those in the black mask 1210 by a gap.

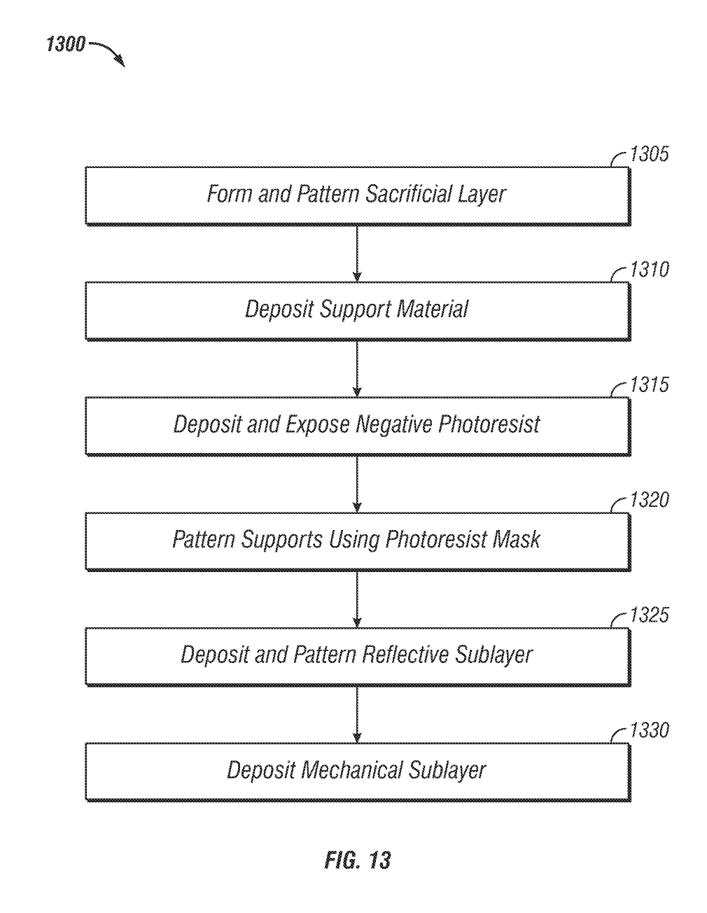

FIG. 13 shows an example of a flow diagram illustrating certain stages in an example of a process of making an electromechanical device using a backside patterning process. As discussed above with respect to FIG. 7F, an electromechanical device may include a deformable layer with a highly reflective sublayer, where the reflective sublayer is located at a distance from support structures. The process 1300 of FIG. 13 begins at a block 1305 in which a sacrificial layer is deposited and patterned to form at least one aperture extending therethrough. The sacrificial layer may be deposited directly over a substrate, or over additional layers, such as conductive layers, optical stacks, or black masks as discussed above.

The process 1300 of FIG. 13 continues at a block 1310 in which a layer of support material is deposited over the patterned sacrificial layer. The process 1300 continues at a block 1315 in which a layer of negative photoresist is deposited over the layer of support material and exposed. The process 1300 continues at a block 1320 in which the support layer is patterned using the exposed photoresist as a mask to form support structures. The process 1300 continues at a block 1325 in which reflective material is deposited and subsequently patterned to remove the portions of the reflective material located adjacent the supports. Finally, the process 1300 continues at a block 1330 in which a mechanical layer is deposited over the patterned reflective layer.

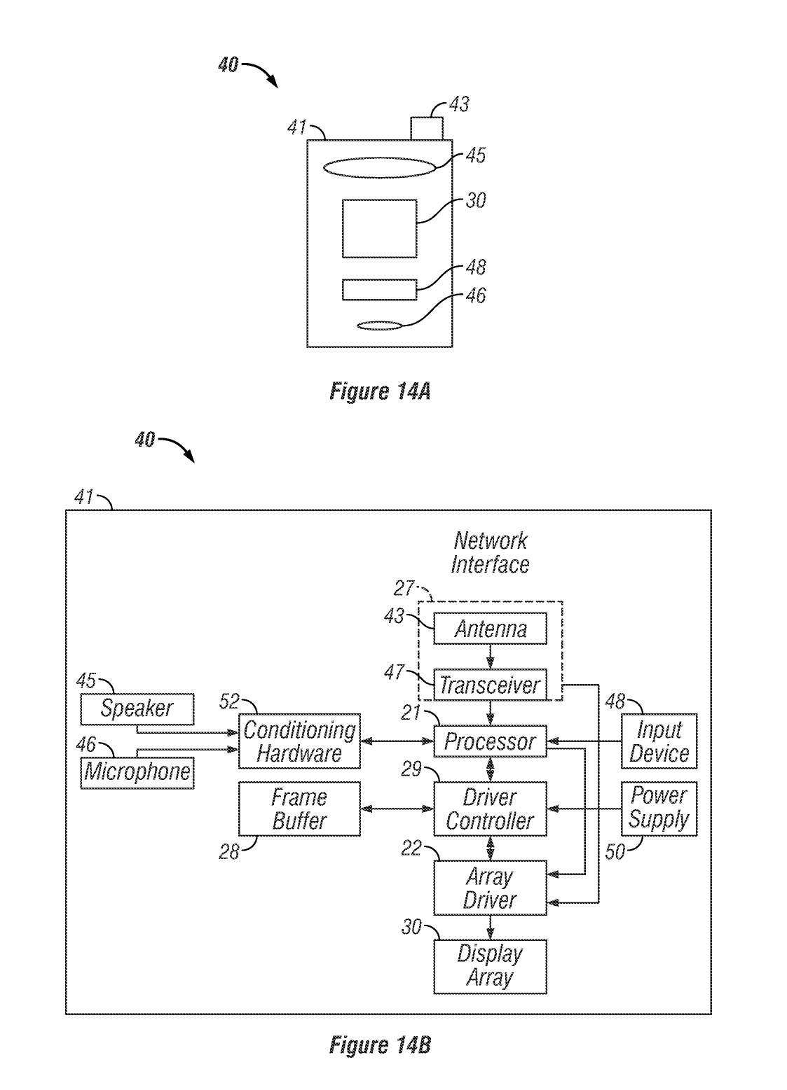

FIGS. 14A and 14B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 11B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of fabricating an electromechanical device, comprising:
forming a black mask over a substrate, wherein the black mask includes:
an absorber layer; and
an opaque layer having at least one aperture formed therein;
forming a sacrificial layer over the substrate, wherein the sacrificial layer includes an opaque material;
patterning the sacrificial layer to form at least one aperture extending through the sacrificial layer, wherein the at least one aperture extending through the sacrificial layer is aligned with the at least one aperture formed in the opaque black mask layer;
forming a layer of structural material over the patterned sacrificial layer;
forming a layer of negative photoresist over the structural material;
exposing the negative photoresist to light through the substrate to form exposed portions of the negative photoresist; and
using the exposed photoresist portions as a mask to etch the structural material to form a patterned structure.

2. The method of claim 1, wherein the structural material includes support material, and wherein etching the structural material to form at least one structure includes forming at least one support.

3. The method of claim 2, further comprising:
forming an optical stack over a substrate, wherein the sacrificial layer is formed over at least a portion of the optical stack; and
forming a deformable reflective layer over the at least one support, wherein the deformable layer is electrostatically displaceable towards the optical stack.

4. The method of claim 3, further comprising removing the sacrificial layer.

5. The method of claim 3, wherein the optical stack comprises:
an absorber layer formed over the substrate; and
an insulating layer formed over the absorber layer.

6. The method of claim 5, further comprising forming a buffer layer over the black mask, wherein the optical stack is formed over the buffer layer.

7. The method of claim 6, further comprising patterning the buffer layer to form at least one via overlying a portion of the black mask, wherein the at least one via is formed prior to forming the optical stack.

8. The method of claim 2, wherein the support is located substantially within the at least one aperture in the sacrificial layer.

9. The method of claim 1, wherein the black mask further comprises a spacer layer located over the absorber layer and below the opaque layer.

10. The method of claim 1, wherein the opaque layer includes a reflective layer.

11. The method of claim 1, wherein the layer of structural material includes a material which is substantially light-transmissive.

12. An electromechanical device, comprising:
a black mask formed over a substrate, the black mask comprising:
an absorber layer; and
an opaque layer having at least one aperture formed therein;
at least one structure, wherein the at least one structure is aligned with the at least one aperture in the reflective layer; and
a deformable layer spaced apart from underlying layers by a gap.

13. The electromechanical device of claim 12, wherein the at least one structure includes a support which spaces the deformable layer apart from underlying layers.

14. The electromechanical device of claim 12, further comprising a conductive layer located over the black mask and separated from the deformable layer by a gap, wherein the deformable layer is electrostatically displaceable towards the conductive layer.

15. The electromechanical device of claim 12, further comprising:
a buffer layer located between the black mask and the conductive layer; and
an insulating layer located between the conductive layer and the deformable layer.

16. The electromechanical device of claim 15, wherein:
the conductive layer includes a partially reflective thickness of an absorber layer; and
the deformable layer includes a reflective sublayer on the side of the deformable layer facing the conductive layer.

17. The electromechanical device of claim 16, wherein the reflective sublayer does not extend over the aperture in the black mask opaque layer.

18. The electromechanical device of claim 12, wherein the opaque black mask layer includes a reflective layer.

19. The electromechanical device of claim 18, wherein the black mask includes a spacer layer overlying the black mask absorber layer and underlying the black mask opaque layer.

20. The electromechanical device of claim 12, wherein the at least one structure includes a material which is substantially light-transmissive.

21. The electromechanical device of claim 12, further comprising:
a processor that is configured to communicate with the electromechanical device, the processor being configured to process image data; and
a memory device that is configured to communicate with the processor.

22. The electromechanical device of claim 21, further comprising:
a driver circuit configured to send at least one signal to the electromechanical device; and
a controller configured to send at least a portion of the image data to the driver circuit.

23. The electromechanical device as recited in claim 21, further comprising:
an image source module configured to send the image data to the processor.

24. The electromechanical device as recited in claim 23, wherein the image source module comprises at least one of a receiver, transceiver, and transmitter.

25. The electromechanical device as recited in claim 21, further comprising:
an input device configured to receive input data and to communicate the input data to the processor.

26. An electromechanical device, comprising:
a stationary conductive layer supported by a substrate;
a plurality of supports;
a movable conductive layer generally spaced apart from the fixed conductive layer by an air gap, wherein the movable conductive layer is supported by the plurality of supports; and
means for shielding at least a portion of the electromechanical device from light passing through the substrate, wherein the shielding means includes partially transmissive regions which allow at least a portion of light passing through the substrate to pass therethrough, wherein the partially transmissive regions underlie the plurality of supports.

27. The electromechanical device of claim 26, wherein the shielding means includes an interferometric black mask, the interferometric black mask comprising:
a partially reflective layer;
a spacer layer; and
a reflective layer.

28. The electromechanical device of claim 27, wherein the reflective layer in the interferometric black mask includes apertures extending therethrough to form the partially transmissive regions of the interferometric black mask.

29. The electromechanical device of claim 28, wherein the fixed conductive layer includes an absorber layer, and wherein the moveable conductive layer includes a reflective layer.

30. The electromechanical device of claim 28, wherein the supports are at least partially transmissive to light.

31. A method of fabricating an electromechanical device, the method comprising:
forming a sacrificial layer over a substrate, wherein the sacrificial layer includes an opaque material;
patterning the sacrificial layer to form a patterned sacrificial layer with at least one aperture extending through the sacrificial layer;
forming a layer of support material over the patterned sacrificial layer;
forming a layer of negative photoresist over the layer of support material;
exposing the layer of negative photoresist to light through the substrate to form exposed portions of the negative photoresist;
using the exposed photoresist portions as a mask to etch the support material to form at least one support;
depositing a layer of reflective material over the support;
patterning the layer of reflective material to remove portions of the reflective material overlying and surrounding the support; and
depositing a mechanical layer over the layer of reflective material.

32. The method of claim 31, further comprising performing a release etch to remove the patterned sacrificial layer.

33. The method of claim 31, further comprising forming an optical stack over the substrate prior to forming the sacrificial layer over the substrate.

34. The method of claim 33, wherein forming the optical stack comprises:
depositing a conductive absorber layer over the substrate; and
depositing an insulating layer over the conductive absorber layer.

35. The method of claim 31, wherein the mechanical layer includes a material which is at least partially transmissive to light.

36. The method of claim 31, wherein the mechanical layer includes a material which is less reflective than the layer of reflective material.

37. An electromechanical device, comprising:
a conductive absorber layer formed over a substrate;
an insulating layer formed over the conductive absorber layer;
a plurality of supports, wherein the plurality of supports are at least partially transmissive to light;
a deformable layer spaced apart from the insulating layer by the plurality of supports, such the deformable layer and the insulating layer are separated by an air gap, wherein the deformable layer comprises:
a mechanical sublayer; and
a reflective sublayer located on the side of the mechanical layer facing the air gap,
wherein the deformable layer is electrostatically actuatable towards the conductive absorber layer such that a substantial portion of the reflective sublayer is collapsed against an underlying layer.

38. The electromechanical device of claim 37, wherein the mechanical layer further includes an upper sublayer located on the side of the divisional, the upper sublayer including the same material as the reflective sublayer.

39. The electromechanical device of claim 37, wherein the mechanical sublayer includes a material which is at least partially transmissive to light.

40. The electromechanical device of claim 37, wherein the mechanical sublayer includes a material which is less reflective than the reflective sublayer.
